(19) United States
(12) Patent Application Publication
(10) Pub. No.: US 2018/0302021 A1
(43) Pub. Date: Oct. 18, 2018

(54) Customizable Modular Solar Power System

(71) Applicants: David R. Hall, Provo, UT (US); Seth Myer, Eagle Mtn., UT (US); Joe Fox, Spanish Fork, UT (US)

(72) Inventors: David R. Hall, Provo, UT (US); Seth Myer, Eagle Mtn., UT (US); Joe Fox, Spanish Fork, UT (US)

(21) Appl. No.: 15/591,504

(22) Filed: May 10, 2017

Related U.S. Application Data
(63) Continuation-in-part of application No. 15/485,824, filed on Apr. 12, 2017.

(51) Int. Cl. H02S 10/20; H02S 20/20; H02S 30/10; H02J 13/00; H02S 40/32; H02S 40/34; H02S 40/38; H01L 31/042

(52) U.S. Cl. CPC H02S 10/20; H02S 20/20; H02S 30/10; H01L 31/042; H02S 40/32; H02S 40/34; H02S 40/38; H02J 13/0096

(57) ABSTRACT

Modular solar systems comprise one or more module units that are connectable into a system/assembly for convenient installation on a roof or other surface that receives solar insolation. The modules are adapted for electrical, and preferably also mechanical, connection into a module assembly, with the number of modules and types of modules selected to handle the required loads. Each module is adapted and designed to handle the entire power of the assembly and to provide or receive control signals for cooperative performance between all the modules and for monitoring and communication regarding the assembly performance and condition. Modules with different functional purposes may be included in the system in order to customize system performance based on situational needs.

### CROSS REFERENCE TO RELATED APPLICATIONS

This application is a continuation-in-part of co-pending U.S. patent application Ser. No. 15/485,824 filed on Apr. 12, 2017 which is hereby incorporated by reference in its entirety.

### FIELD OF THE INVENTION

This invention generally relates to modular solar systems that comprise one or more module units that are connectable into a system/assembly for convenient installation on a roof or other surface that receives solar insolation. The modules are adapted for electrical, and preferably also mechanical, connection into a module assembly, with the number of modules and types of modules selected to handle the required loads. Each module is adapted and designed to handle the entire power of the assembly and to provide or receive control signals for cooperative performance between all the modules and for monitoring and communication regarding the assembly performance and condition.

### BACKGROUND OF THE INVENTION

For AC power systems (and all power systems where there is a load and a supply), the generation (supply power) and demand (load) must be equal. In other words, the Utility Supply must equal the Customer Load. If there is ever a power outage, the re-connection of the circuits after the fault is cleared must be done carefully to assure that the loads are connected in a phased or staged fashion. This assures that the required balance is maintained while restoring power.

AC distribution systems are designed in such a way to allow this. There are distribution systems (with protection in the form of fuses and circuit breakers) with switches to allow each part of the system to be isolated and controlled.

On both sides (supply and demand) of a conventional Utility Grid, the system is designed in sections or blocks of power to allow for this distribution and equalization. These divisions are isolated by circuit breakers, load centers, distribution panels, transformers and utility substations. This is because the power needs to be carefully distributed from available generation systems that are in turn delivered to quantified loads that are supplied over wiring and distribution circuiting sized to handle the specific power for each circuit.

Solar-powered autonomous devices have been designed for emergency use (for example, during power outage in a hurricane or other catastrophe), or for other non-grid-tied applications, wherein “autonomous” herein means the device is designed for, and relies solely on, solar-panel charging of batteries or other energy-storage devices, without a grid tie. Such conventional autonomous devices do not include the balance of supply and demand that is included in certain embodiments of the invention, and are not modularly-expandable, by connecting multiple modules, as are certain embodiments of the invention. Such conventional autonomous devices are built in a specific system, or “emergency box”, size, and cannot be expanded beyond that single size and power-producing capability. So, such conventional autonomous devices cannot be expanded to serve a larger load than the single “box” size is designed for. The only choice for serving larger loads with such conventional autonomous systems is to buy a bigger system, that is, a bigger, single “emergency box” with higher load-serving capacity.

### SUMMARY

This invention has been developed in response to the present state of the art and, in particular, in response to the problems and needs in the art that have not yet been fully solved by currently available systems and methods. Features and advantages of different embodiments of the invention will become more fully apparent from the following description and appended claims, or may be learned by practice of the invention as set forth hereinafter.

Consistent with the foregoing, a system is disclosed for a solar-powered module, and assemblies of solar-power modules, wherein the modularity allows easy transport and installation on a building roof or other surface where solar insolation occurs. The modules are each adapted for electrical, and preferably also mechanical, connection into a module assembly, wherein additional modules are added, possibly in the form of subordinate modules, primary modules, main modules, or some other module type, to handle the required loads and to provide control of each of the modules, for example, to control how the solar panels charge the energy-storage devices of each and all the modules via a DC system, and to load-shed according to predetermined outlet/load priorities. Each module is adapted and designed to handle the entire load of the assembly and to provide or receive control signals for cooperative performance between all the modules and for monitoring and communication regarding the assembly performance and condition.

Each module in the preferred system is designed with a higher system load rating than what would normally be required for a single module, so that future applications/uses may be served even when the total served load changes. Each individual module is therefore “ready” to accept these higher loads, if and when the individual module is placed in a larger system, that is, placed in an assembly of connected modules. Thus, while, in certain embodiments, some or all of the modules are operable and effective in single-module applications, the preferred modules are “pre-sized” or “pre-adapted” to handle combined loads of several modules connected together. In other words, each preferred module is sized to accommodate the loads of multiple modules and will act as a sub-panel within the assembly of modules, but the preferred modules are electrically, and preferably mechanically, connectable and operable, without requiring any conventional AC system service panel or sub-panel to be added to the assembly of modules, and without requiring the services of an electrician.

Many objects of certain embodiments of the invention will become apparent from the following description, to solve needs for conveniently-packaged and shipped modules of uniform dimensions, convenient and clear electrical and mechanical connectability, as well as convenient and clear status and performance monitoring and reporting.

### BRIEF DESCRIPTION OF THE DRAWINGS

In order that the advantages of the invention will be readily understood, a more particular description of the invention briefly described above will be rendered by reference to specific embodiments illustrated in the appended drawings. Understanding that these drawings depict only typical embodiments of the invention and are not therefore to be considered limiting of its scope, the invention will be described and explained with additional specificity and detail through use of the accompanying drawings, in which:

FIG. 1 is a perspective view of a single module, according to one example embodiment.

FIG. 2 is a perspective view of the invention, an array of several of the modules of FIG. 1 connected together, according to one example embodiment.

FIG. 3A is an enlarged cross-section view, along the line 3A-3A in FIG. 2, of a connection between two adjacent modules, according to one example embodiment.

FIG. 3B is an enlarged cross-section view, viewed along 3B-3B in FIG. 4B, of a side edge of a module that is not adjacent to another module, with a channel cover that is slid onto that side edge to cover and protect said side edge and its electrical elements, according to one example embodiment.

FIG. 4A is a perspective view of an open module showing the airflow thru the enclosure, according to one example embodiments.

FIG. 4B is a top view of six modules connected into an assembly, schematically showing cool air flowing into the lower ends of preferably all the modules, and relatively hot air exiting the upper ends of preferably all the modules, so that hot interior air from each module does not travel through any other module before exiting to the environment of the assembly, according to one example embodiment.

FIG. 5A shows the interior of the module of FIG. 1 with all of the preferred components shown, according to one example embodiment.

FIG. 5B is a cross section of the module, along the line 5B-5B in FIG. 5A, showing the batteries, and insulation, according to one example embodiment.

FIGS. 6A, 6B and 6C are diagrams that show three different array configurations to illustrate certain ways various modules can be connected together, according to some example embodiments.

FIG. 7 is a schematic diagram of several modules connected together with DC power as the main combining feeder circuit, according to one example embodiment.

FIG. 8 shows that modules can be connected to an alternate power supply from which the module can draw power to charge the energy-storage devices of the modules, according to one example embodiment.

FIG. 9 is a wiring diagram of an individual module, according to one example embodiment.

FIGS. 10A and 10B are isometric views of an individual module showing that various different types of outlets serving the loads are possible as a part of the module and are attachable to the module by various different methods, according to example embodiments.

FIGS. 11A, 11B and 11C show how modules of different functions including the normal module, production module, storage module and inverter module, may be connected into a system in order to improve system performance based on varying conditions and needs, according to example embodiments.

FIGS. 12A and 12B show that energy-storage devices may be added to and removed from the storage module and the normal modules with the purpose of changing the energy storage capacity of the system, according to example embodiments.

### DETAILED DESCRIPTION OF THE DRAWINGS

The description that follows includes systems, methods, techniques, instruction sequences, and computing machine program products that embody illustrative embodiments of the disclosure. In the following description, for the purposes of explanation, numerous specific details are set forth in order to provide an understanding of various embodiments of the inventive subject matter. It will be evident, however, to those skilled in the art, that embodiments of the inventive subject matter may be practiced without these specific details. In general, well-known instruction instances, protocols, structures, and techniques are not necessarily shown in detail.

In various embodiments, a system as described herein determines how a customizable modular solar power system is functionally accomplished.

Reference throughout this specification to “one embodiment,” “an embodiment,” or similar language means that a particular feature, structure, or characteristic described in connection with the embodiment is included in at least one embodiment. Thus, appearances of the phrases “in one embodiment,” “in an embodiment,” and similar language throughout this specification may, but do not necessarily, all refer to the same embodiment, but mean “one or more but not all embodiments” unless expressly specified otherwise. The terms “including,” “comprising,” “having,” and variations thereof mean “including but not limited to” unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise.

Furthermore, the described features, advantages, and characteristics of the embodiments may be combined in any suitable manner. One skilled in the relevant art will recognize that the embodiments may be practiced without one or more of the specific features or advantages of a particular embodiment. In other instances, additional features and advantages may be recognized in certain embodiments that may not be present in all embodiments.

These features and advantages of the embodiments will become more fully apparent from the following description and appended claims, or may be learned by the practice of embodiments as set forth hereinafter. As will be appreciated by one skilled in the art, aspects of the present invention may be embodied as a system, method, and/or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module,” or “system.” Furthermore, aspects of the present invention may take the form of a computer program product embodied in one or more computer readable medium(s) having program code embodied thereon.

Many of the functional units described in this specification have been labeled as modules, in order to more particularly emphasize their implementation independence.

For example, a module may be implemented as a hardware circuit comprising custom VLSI circuits or gate arrays, off-the-shelf semiconductors such as logic chips, transistors, or other discrete components. A module may also be implemented in programmable hardware devices such as field programmable gate arrays, programmable array logic, programmable logic devices or the like.

Modules may also be implemented in software for execution by various types of processors. An identified module of program code may, for instance, comprise one or more physical or logical blocks of computer instructions which may, for instance, be organized as an object, procedure, or function. Nevertheless, the executables of an identified module need not be physically located together, but may comprise disparate instructions stored in different locations which, when joined logically together, comprise the module and achieve the stated purpose for the module.

Indeed, a module of program code may be a single instruction, or many instructions, and may even be distributed over several different code segments, among different programs, and across several memory devices. Similarly, operational data may be identified and illustrated herein within modules, and may be embodied in any suitable form and organized within any suitable type of data structure. The operational data may be collected as a single data set, or may be distributed over different locations including over different storage devices, and may exist, at least partially, merely as electronic signals on a system or network. Where a module or portions of a module are implemented in software, the program code may be stored and/or propagated on in one or more computer readable medium(s).

The computer readable medium may be a tangible computer readable storage medium storing the program code. The computer readable storage medium may be, for example, but is not limited to, an electronic, magnetic, optical, electromagnetic, infrared, holographic, micromechanical, or semiconductor system, apparatus, or device, or any suitable combination of the foregoing.

More specific examples of the computer readable storage medium may include but are not limited to a portable computer diskette, a hard disk, a random access memory (RAM), a read-only memory (ROM), an erasable programmable read-only memory (EPROM or Flash memory), a portable compact disc read-only memory (CD-ROM), a digital versatile disc (DVD), an optical storage device, a magnetic storage device, a holographic storage medium, a micromechanical storage device, or any suitable combination of the foregoing. In the context of this document, a computer readable storage medium may be any tangible medium that can contain, and/or store program code for use by and/or in connection with an instruction execution system, apparatus, or device. Computer readable storage medium excludes computer readable signal medium and signals per se.

The computer readable medium may also be a computer readable signal medium. A computer readable signal medium may include a propagated data signal with program code embodied therein, for example, in baseband or as part of a carrier wave. Such a propagated signal may take any of a variety of forms, including, but not limited to, electrical, electro-magnetic, magnetic, optical, or any suitable combination thereof. A computer readable signal medium may be any computer readable medium that is not a computer readable storage medium and that can communicate, propagate, or transport program code for use by or in connection with an instruction execution system, apparatus, or device. Program code embodied on a computer readable signal medium may be transmitted using any appropriate medium, including but not limited to wire-line, optical fiber, Radio Frequency (RF), or the like, or any suitable combination of the foregoing.

In one embodiment, the computer readable medium may comprise a combination of one or more computer readable storage mediums and one or more computer readable signal mediums. For example, program code may be both propagated as an electro-magnetic signal through a fiber optic cable for execution by a processor and stored on RAM storage device for execution by the processor.

Program code for carrying out operations for aspects of the present invention may be written in any combination of one or more programming languages, including an object oriented programming language such as Java, Smalltalk, C++, PHP or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The computer program product may be shared, simultaneously serving multiple customers in a flexible, automated fashion. The computer program product may be standardized, requiring little customization and scalable, providing capacity on demand in a pay-as-you-go model. The computer program product may be stored on a shared file system accessible from one or more servers.

The computer program product may be integrated into a client, server and network environment by providing for the computer program product to coexist with applications, operating systems and network operating systems software and then installing the computer program product on the clients and servers in the environment where the computer program product will function.

In one embodiment software is identified on the clients and servers including the network operating system where the computer program product will be deployed that are required by the computer program product or that work in conjunction with the computer program product. This includes the network operating system that is software that enhances a basic operating system by adding networking features.

Furthermore, the described features, structures, or characteristics of the embodiments may be combined in any suitable manner. In the following description, numerous specific details are provided, such as examples of programming, software modules, user selections, network transactions, database queries, database structures, hardware modules, hardware circuits, hardware chips, etc., to provide a thorough understanding of embodiments. One skilled in the relevant art will recognize, however, that embodiments may be practiced without one or more of the specific details, or with other methods, components, materials, and so forth. In other instances, well-known structures, materials, or operations are not shown or described in detail to avoid obscuring aspects of an embodiment.

Aspects of the embodiments are described below with reference to schematic flowchart diagrams and/or schematic block diagrams of methods, apparatuses, systems, and computer program products according to embodiments of the invention. It will be understood that each block of the schematic flowchart diagrams and/or schematic block diagrams, and combinations of blocks in the schematic flowchart diagrams and/or schematic block diagrams, can be implemented by program code. The program code may be provided to a processor of a general purpose computer, special purpose computer, sequencer, or other programmable data processing apparatus to produce a machine, such that the instructions, which execute via the processor of the computer or other programmable data processing apparatus, create means for implementing the functions/acts specified in the schematic flowchart diagrams and/or schematic block diagrams block or blocks.

The program code may also be stored in a computer readable medium that can direct a computer, other programmable data processing apparatus, or other devices to function in a particular manner, such that the instructions stored in the computer readable medium produce an article of manufacture including instructions which implement the function/act specified in the schematic flowchart diagrams and/or schematic block diagrams block or blocks.

The program code may also be loaded onto a computer, other programmable data processing apparatus, or other devices to cause a series of operational steps to be performed on the computer, other programmable apparatus or other devices to produce a computer implemented process such that the program code which executed on the computer or other programmable apparatus provide processes for implementing the functions/acts specified in the flowchart and/or block diagram block or blocks.

The schematic flowchart diagrams and/or schematic block diagrams in the Figures illustrate the architecture, functionality, and operation of possible implementations of apparatuses, systems, methods and computer program products according to various embodiments of the present invention. In this regard, each block in the schematic flowchart diagrams and/or schematic block diagrams may represent a module, segment, or portion of code, which comprises one or more executable instructions of the program code for implementing the specified logical function(s).

It should also be noted that, in some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. Other steps and methods may be conceived that are equivalent in function, logic, or effect to one or more blocks, or portions thereof, of the illustrated Figures. [0040] Although various arrow types and line types may be employed in the flowchart and/or block diagrams, they are understood not to limit the scope of the corresponding embodiments. Indeed, some arrows or other connectors may be used to indicate only the logical flow of the depicted embodiment. For instance, an arrow may indicate a waiting or monitoring period of unspecified duration between enumerated steps of the depicted embodiment. It will also be noted that each block of the block diagrams and/or flowchart diagrams, and combinations of blocks in the block diagrams and/or flowchart diagrams, can be implemented by special purpose hardware-based systems that perform the specified functions or acts, or combinations of special purpose hardware and program code.

Certain embodiments of the invented Customizable Modular Solar Power System (CMSPS) are for meeting the needs of an individual home, apartment building, individual business building, or other individual building, to supplement, or supply entirely, said home's or building's energy needs. While the CMSPS is of a scale and structure that is efficiently shipped, installed, and operated on a single home or building, the CMSPS is specially adapted to have features similar to those of a much larger power system, that is, of a AC Utility Power Grid/System. More specifically, said features comprise that the system is divided into individual modules that can be controlled and balanced with each other, the solar supply power, and the loads they are serving.

The CMSPS comprises, consists essentially of, or consists of, at least one module, and preferably multiple of said modules, that can each operate and function independently. The module is a complete solar powered power supply with energy storage that is completely self-contained. Even in an individual module, the supply and demand must be managed and controlled.

The preferred system comprises, consists essentially of, or consists of, multiple modules connected together to increase the overall power of the system in order to serve larger loads. A single module may be only capable of serving a 10 amp, 120V load. However, multiple modules when connected together would be capable of serving much larger loads (60 amps at 240 volts).

The Inventor has determined that multiple solar power supplies cannot be just “simply connected” together, and so connection of multiple of the CMSPS modules is specially designed and structured to include features that are not included in conventional “solar in a box”, “plug and play solar panels”, or “emergency solar box generators”. The inventor has determined that each sub-system (module) of the CMSPS must be integrated through a distribution system that: 1) Assures that each power generating system is balanced with the energy storage system(s), and the electrical loads within the module; 2) Has circuit protection to protect against and isolate faults; and 3) Actively manages the power between the modules (system balancing).

The approach taken to assure that this is done properly is to design each module with the interfacing bus bar or wiring, for electrically connecting the multiple modules, being sized to accommodate the full load of the combined system (once multiple modules are connected together). The bus bar may comprise a solid or tubular cross-sectional shape selected from the group consisting of circles, conic sections, and polygons, such as circles, cones, ellipse, ovals, squares, rectangles, triangles, hexagons, octagons, and pentagons to maximize the efficiency of the connection. The bus bar may be a solid or a tube having such cross-sectional shape. The circuit protection, monitoring and control are also designed to allow the balancing of the system, along with isolating faults in the system to allow the system to continue to operate when there is a failure in one of the system components. For example, if one battery bank is failing, the system isolates this bank from the rest of the system in order to allow the remaining battery banks to operate without having the bad bank bringing down the entire system (potentially lowering the voltage to a point that the loads can no longer be served).

Either the main module, the primary module, or other module type used for systems requiring higher power, contains all of the system power, monitoring and control features for a complete and operational system. Additional subordinate modules can be connected to the primary module in order to increase the overall power of the system. Each module has a specific rating called the load rating that corresponds to the size of the load that it is capable of supplying. Each module has both a local load rating and a system load rating. The local load rating corresponds to the amount of power that the individual module can supply directly, while the system load rating corresponds to the size of the load that the entire system of connected modules can supply. In other words, if the largest load to be expected from the system after all modules are connected together will be 5 kW, then the primary and subordinate modules must all have a system load rating equal to or greater than 5 kW, even though the local load ratings of the individual modules may be less than that, for example 1 kW. This assures that, once all of the modules are connected together, the combined load over the bus bar and/or interconnection wiring is large enough to handle this maximum load. The monitoring and control system prevents the electrical interconnection of modules with incompatible local and system load ratings. The local and system load ratings are determined when the module is manufactured and do not change after that. In other words, the system load rating of a subordinate module will not increase if the module is connected to a system of modules that supplies a very large load.

For individual modules, there also exists ratings for power production and storage capabilities. These are called local production rating and local storage rating. These correspond to how much solar power each module can produce and how much power each module can store, respectively. Both of these ratings are determined when the module is manufactured and do not change after that unless the module is altered in some way, for example the energy-storage device is replaced by one with greater storing capacity. Unlike the system load rating mentioned previously, there is not a manufacturable system production rating or system storage rating since these ratings will both change depending on the size of the system into which the individual modules are connected. Thus, individual modules do not have a system rating for either production or storage but the system of modules as a whole, once all connected, will have system ratings for production and storage.

As an example, the local storage rating of a single module may be 2.5 kWh (storage capacity) with a local production rating of 500 W, and a system load rating of 5 kW. If four (4) of these modules are connected into a system, the system load ratings of each module would be high enough to allow the electrical interconnections of the modules to occur. The system storage rating would be 10 kWh (4 modules at 2.5 kWh each) and the system production rating would be 2 kW (4 modules at 500W each).

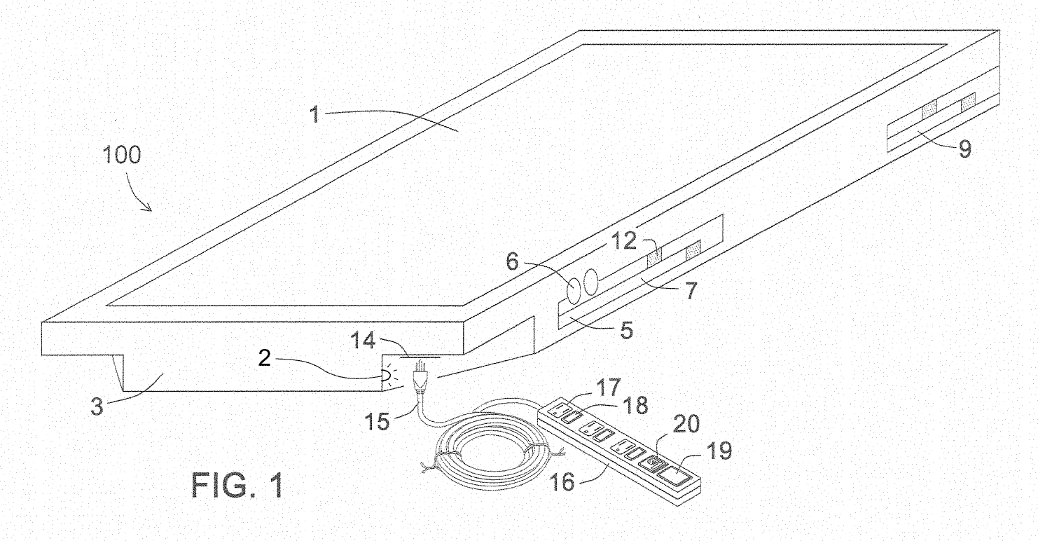

The modules are electrically connected by means of interconnection bus bars (which preferably also mechanically connect the modules) and/or wiring, which allow the sharing of power between the modules. While bus bars are preferred in certain embodiments, wiring by means of electrically-conductive wire or cable may be the interconnection means, or may supplement a bus bar interconnection means. The bus bar may comprise a solid or tubular cross-sectional shape selected from the group consisting of circles, conic sections, and polygons, such as circles, cones, ellipse, ovals, squares, rectangles, triangles, hexagons, octagons, and pentagons to maximize the efficiency of the connection. The DC electrical connection is shared over the bus bar or wiring interconnection. In addition to DC interconnection, the monitoring or network interconnected is also done by means of said interconnection bus bars or wiring. See FIG. 1, call-out numbers 7 and 9. Each of these systems (DC and data) are kept separated and isolated from each other over the bus bar and/or wiring interconnection.

The primary (P) module can be viewed as an electrical load center or main service panel that serves the load(s). All of the subordinate (S) modules feed into the P module in order to supply the combined power required for the system. Thus, the load(s) served via the P module are supported by the power capacity of the total system. For example, 4 modules at 500 watts each connected together would be able to serve 2 kW of load.

The P module has circuit protection (fuses and/or circuit breakers) as well as controls to allow the isolation and control of each of the interconnected S modules. Both supply and load power, within each module and also within the system (that is, the combined system of P module and S modules), are able to be controlled, balanced and modified (if required—load shedding or isolating faults) by the control system (or “controller”) of the P module.

For embodiments that require more power than a single P module with multiple S modules can provide, then 2 or more P modules can be connected to serve these larger loads. If multiple, connected P modules are not enough, certain embodiments are designed to allow the integration of 2 CMSPS systems. This is accomplished by adding a main (M) module that has higher load ratings than the P modules. So, for example, if the system is maxed out with (4) 2 kW P modules (for a total of 8 kW) and more power is needed, an M module with a system load rating of 20 kW could be added to the system. For example, each of 4 P modules would be connected to the M module, and additional P modules (with attached S modules) could then be added to the entire assembly in order to achieve the higher capacity. The M module would be the only component that would need to have the highest rating, since each system would be feeding into M module, and would only be exposed to the lower rating. Module M, along with its output receptacle, would be rated for the highest capacity as required. The module naming convention and the associated numbers given in this example are not meant to be limiting in scope but are only meant to illustrate the expandability of the solar modular system. There may be a module with load ratings higher than the M module given in this example that could be used in a system to produce as much power as needed, according to specifications.

The inventor has determined that there are 2 requirements in order to combine multiple modules according to preferred embodiments of the invention:
1. Because the total CMSPS (or “total system”) power delivered (and the power produced from the solar) is higher for multiple modules, each individual module must be capable of supporting the total system power. So, if a single module, only capable of producing 500 watts by itself, is placed into a system that is capable of producing 2 kW, the individual module must be able to handle the higher load of 2 kW. Any shared components must be rated for the total or shared system load ratings once they are connected together. The electrical conductors (bus bar and/or wire) must be sized to accommodate the total system load (not just the load of one module).
2. In order to benefit from the total system power of the combined modules, each module must be connected to the other modules in the system. This connection allows for the sharing of stored energy (higher storage capacity compared to a single module). It also increases the available instantaneous power—the number of amps that can be delivered in real time. This provides a higher inrush current for loads that require higher amperage than a single module can deliver.

Structural changes in the modules that are required in certain embodiments so that each module is adapted and designed to handle the entire load of the assembly, may include one or more, and typically all, of the following:
1. In order to interconnect multiple modules, the bus bar or wiring that connects multiple modules must be sized large enough to handle the combined loads served by the total system (with multiple modules connected together). This bus bar is preferred for the desired modularity, but, in certain embodiments wherein only one module will be used, it is not required. The bus bar may comprise a solid or tubular cross-sectional shape selected from the group consisting of circles, conic sections, and polygons, such as circles, cones, ellipse, ovals, squares, rectangles, triangles, hexagons, octagons, and pentagons to maximize the efficiency of the connection. The bus bar may be a solid or a tube having such cross-sectional shape. The bus bar may comprise a combination of said shapes. The modules may be connected by bus bars having different shapes.
2. With multiple modules connected together, there must be circuit protection (circuit breakers) for safety and to isolate faults within each module, and to separate these faults from the interconnected modules. The circuit breakers serve the purpose of power distribution to other modules, providing the capability of isolating one module from the other modules in the system (if there is a fault within that module) while still maintaining the full operation of the system—removing the one problem module from the loop.
3. The parallel wiring (bus bar) along with the control system provide a way to manage the combining of the power from multiple modules. The control system allows the power to be distributed and controlled to serve the multiple loads as required. For example, if there are 240 volt loads along with 120 volt loads, the distribution system controls the output required to serve these different loads. The combined power of several modules can be leveraged to serve the larger loads, while still being able to maintain the smaller loads via a separate lower voltage outlet. The control system is an important feature of the connections between the modules, and turns on and off circuits as required.

From a safety and control standpoint, there are also requirements. Each circuit must be protected from an electrical fault. This is done with fuses and/or circuit breakers. For control, each subsystem/component must have a method of being connected to or disconnected from the system. This is done with relays, switches and/or electronic control systems (with transistors and the like). This applies locally (to one module) and to the whole system (whole assembly). Once the modules are physically connected (and electrically connected) this isolation and control extends across the whole system/assembly.

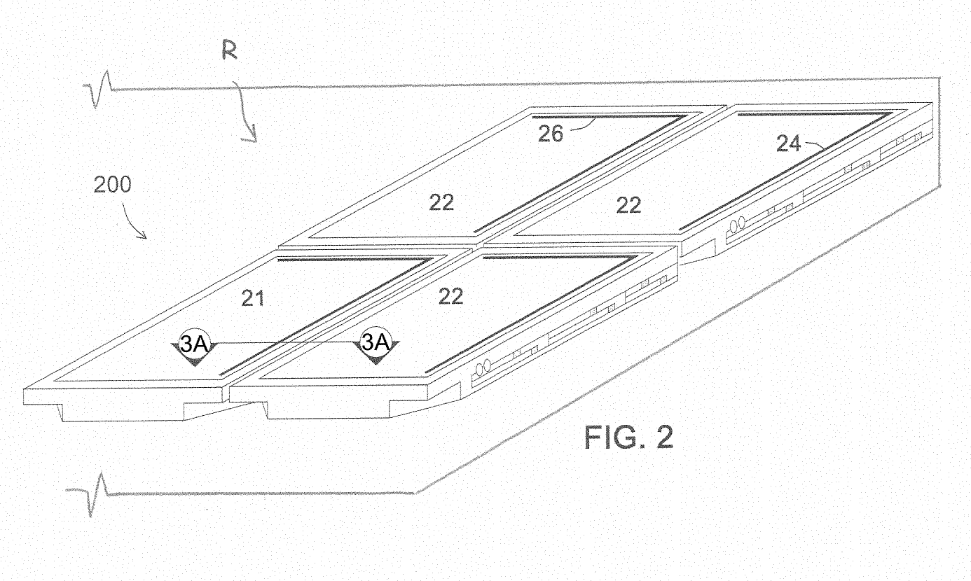

The control system is comprised of a main controller located in the P module or the M module. Each module that is connected to the main controller also has a controller that connects that module to the main controller, and controls everything within that individual module. The part of the control system that is down at ground level is the user interface device to the control system. It allows the user to monitor and control the system from there, without having to climb up on the roof R (schematically shown in FIG. 2). A similar interface may be provided via the wireless connection to the internet. For systems with this wireless interface, the user can monitor and control the entire system (and individual modules connected via the wireless) on their computer via the web interface.

With a small system (only P modules), the P module's controller is the main controller of the system. Once the P module(s) are connected to an M module, the M module becomes the main controller. All controllers are networked to the main controller, and any global monitoring or control actions are carried out through this main controller.

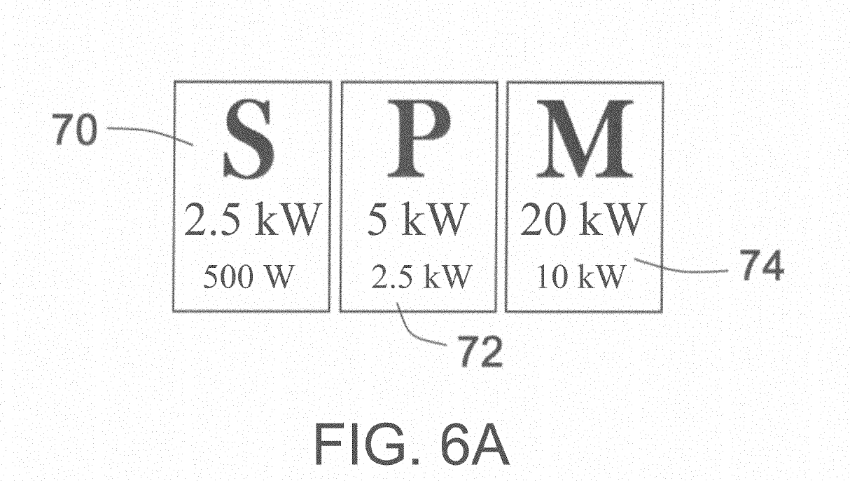

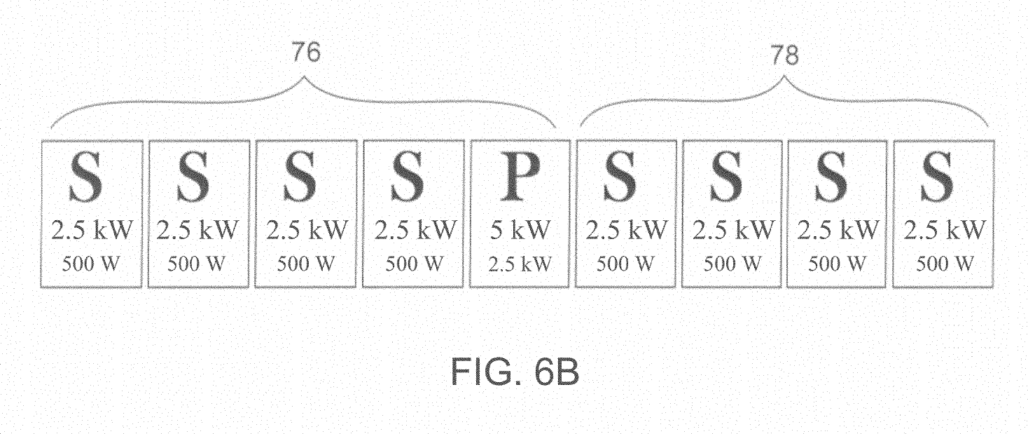

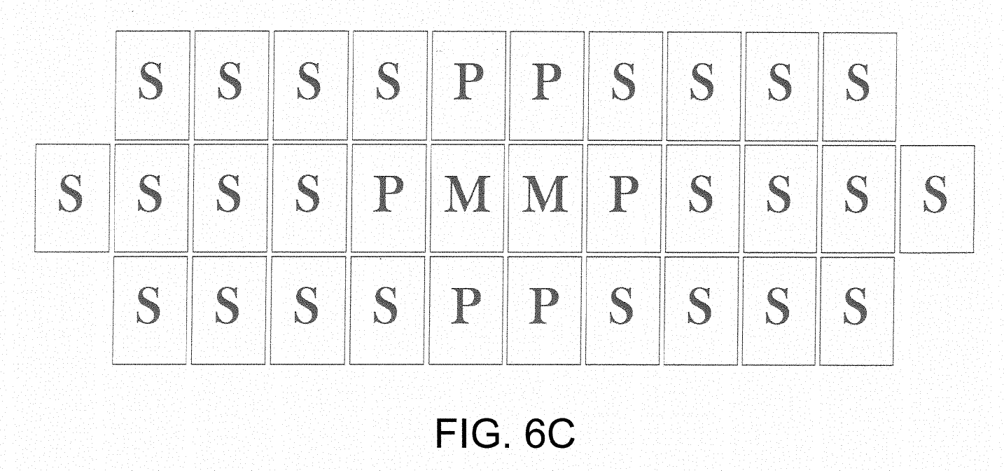

The control system (CS, or also “controller”) monitors and controls the connection of additional modules. In order to connect multiple modules, the P module is the first one in the system. The P module can operate by itself with no other modules connected to it. In order to increase the total system power, additional S modules can be connected to the P module. As each S module is connected to the system (placed in line with a number of S modules with P at the head of the system), the control system will confirm that the S modules are compatible and will make the electrical connections required in order to incorporate the additional S module into that system. Additional S modules can be placed into the system until the total rated system power has been reached (or, a “full” system). If an additional module is attempted to be placed into a full system, the CS will alert the user with audible and/or visual notifications that the max has been reached. If the user ignores the warnings, the CS will not allow the module to be electrically connected (even if it is mechanically connected). For every system, there is a limit to the number of modules that can be connected to that system. In the example shown in FIG. 6B, the maximum number of S modules that can be connected to the P module are shown. If you attempt to connect an additional S module to this system (a ninth S module—beyond the 8 S modules shown), the system will be overloaded. At this point, the only way to expand the system beyond 8 S modules is to add an additional P module. The factory preset does not allow the system to operate with more modules connected than the rating allows. There are user-selected defaults that will allow for the mechanical connection to occur, however, the electrical connection will not occur and an audible or visual warning will occur. The user interface device will indicate what the problem is (ie: too many modules connected to system).

The CS monitors and controls all of the system functions, as are described herein and/or as will be understood by one of skill in the art after reading and viewing this document and the drawings. The CS is connected by wiring (data wiring, Ethernet or similar) to the control unit. While the solar modules are typically placed up on the roof or in an otherwise elevated position, the control system user interface device is typically down at ground level so that it is accessible to the user. The CS can also be connected via wireless (WIFI, Bluetooth, or similar) to the internet so that the user interface device is remote such as a phone or computer.

In certain embodiments, if there are problems with the system that cannot be resolved by the user locally, the CS can be accessed by personnel at a remote help desk. In certain embodiments, all of the system functions (both monitoring and control) can be done remotely provided that there is an internet connection. The local connection to the internet can also be powered by the CMSPS to assure that this feature is always available (even when there is a utility power outage).

Every system issue that arises (faults, under-voltage, over-voltage, over-current, battery failure, etc.) may be reported to the CS and a notification is sent to the user interface device based on the nature of the issue. For serious issues (fault or complete system failure) there are default settings that immediately and automatically cause the CS to take required actions. For example, for a catastrophic event (for example, tree falls on module and completely crushes it), the CS will shut down all systems immediately to prevent further electrical damage to the system. All circuits would be “opened” by switches and other means to disconnect and shut down the electrical system. Other less serious issues may be reported to the CS and a notification sent to the user interface device (for example, a “trouble”, “notification”, or “alarm” notification, etc.) and an audible and/or visual alarms would sound based on the nature and severity of the problem.

In order to maintain the total storage capacity of the system, the CS continuously monitors the health of the batteries. The Energy Management System (EMS) monitors the power production (from solar) and controls how much power is delivered to the loads. There are many factors that affect the storage capacity of the system. How much solar energy is available on any given day is one of the main factors. If there are multiple cloudy days, the CS will conserve the amount of power that is delivered to the loads in order to maintain the most important operational features/apparatus if there is minimized energy production.

Temperature can also influence battery health. The EMS is equipped with temperature sensors that report the temperature of the electronics and the batteries. Cooling systems for overheating are preferably included, and can be turned on when temperatures exceed a maximum level (pre-set at the factory based on the battery type). When temperatures drop below a minimum, actions are taken to keep the battery healthy in these conditions. Some of these actions preferably include turning off a “fresh air” electronics cooling fan, and turning on an internal “re-circulating” fan that distributes the electronics compartment air into the battery compartment.

In addition to insulation around the batteries, phase change material may also be utilized to even out the temperature swings from day to night. This prevents both temperature extremes (too hot or too cold). In addition to these components, the batteries may be placed on a conductive plate (copper or aluminum or other conducting material) that is shared with the electronic components compartment. During the summer or hot days, the amount of heat transferred from the electronics compartment to the battery compartment will be minimal. This is due in part to the fact that the fresh air fan will be keeping the electronics compartment cool when it is hot outside. When the air is cold outside, the heat from the electronics compartment will be conducted through the base plate to the batteries to help them stay warm.

Batteries do produce a small amount of heat when they are charging and discharging. By connecting several modules together, it is possible to use batteries from one module to charge batteries from another module in this case. There can also be a small heater in the battery compartment for geographic locations that are extremely cold.

The way load shedding is controlled is via a load shedding (LS) feature that is selected by the user. There is a minimum of two power outlets (or receptacles) at the module(s), and preferably at three power outlets (or receptacles). The priority of each receptacle is indicated to, and known by, the user in advance, and the user plugs-in/connects the loads accordingly depending on the user's perception of the importance/priority of the loads. For example, if there were three receptacles and levels of load shedding ranked as A—Highest importance to C—Lowest priority loads, the user would determine the load importance/priority and plug-in/connect them accordingly to the receptacles. Thus, in the event of a shortage of solar/battery power, the LS system would “shed” the lowest priority loads first by disconnecting (turning off a switch or relay) the C receptacle. All loads plugged into this circuit would be turned off if the stored power dropped below a preset level. After turning off load C, the second level would turn off the B loads before the highest priority loads were at risk of being turned off.

Under normal conditions, all three circuits would be fully operational. In addition to the circuit management explained above, there are also lighting circuits that could be dimmed to conserve energy. Any and all of the circuits (A, B and C) can be programmed as dimming circuits, and the dimming parameters can be pre-set to dim as required when energy needs to be conserved.

LED indicators at the user interface device show the system status. For example, if all circuits are fully charged and operational, the LEDs would show a Green illuminated LED for circuit A, Yellow for B, and Red for C. In the case where load shedding is occurring, a flashing LED shows that it is in transition, and once circuit C is turned off, the Red LED would no longer be illuminated.

The interconnection of the modules can be done primarily over the DC power system wiring. The preferred method is to have DC wiring systems shared between the modules.

Shared DC connections allows for sharing of the stored energy between the modules on the DC system, along with allowing the energy produced from the solar panels to be allocated across several modules for storage as needed. If one module is not collecting enough solar energy to keep its batteries charged, the other connected modules can charge the batteries of any and all batteries within the connected system. The control system determines not only which battery bank(s) within the individual module are to be charged, but also allows battery banks in any of the connected modules to be charged by any of the other connected modules.

From a power delivery standpoint, shared DC power between modules allows more energy to be delivered to connected loads, both instantaneous power (in rush current, for example) and total power capabilities are increased according to the number of modules connected together. All energy available can be delivered to any of the connected loads. So if there is only one module rated for 500 watts of power and an instantaneous current maximum of 5 amps, once two of these modules are connected together, they will have double the capacity (1kW of power and 10 amps current).

The CMSPS is equipped with the load shedding capabilities as described above. In a small CMSPS with one or a few modules, the power is distributed to the loads via the plug strip as shown in FIG. 1 (see call-out reference 16). Each receptacle can be turned on or off by the control system to allow lower priority loads to be “shed” when the total stored energy drops below a pre-set level.

For a larger CMSPS, the connection to the loads served is made via an electrical sub-panel. All circuits that are to be served by the CMSPS are connected to the CMSPS sub-panel. In an autonomous system (not grid-connected) these circuits are isolated from (not connected to in any way) any and all of the normal grid-connected circuits. When both types of circuits are present, the outlets or receptacles connected to the CMSPS are identified (color corresponding to priority levels for load shedding) so that the user can identify which circuits are available for CMSPS loads to be plugged into.

All loads served by the small CMSPS are plugged into the power strip that allows each circuit to be managed by the control system. Load shedding is done by switching on or off each receptacle in the plug strip. Each receptacle in the plug strip has an indicator light next to it showing whether or not that individual receptacle or circuit is active or not. The color of each indicator light identifies which circuit and which priority each receptacle serves. Lower priority circuits are shed first, keeping the higher circuits active.

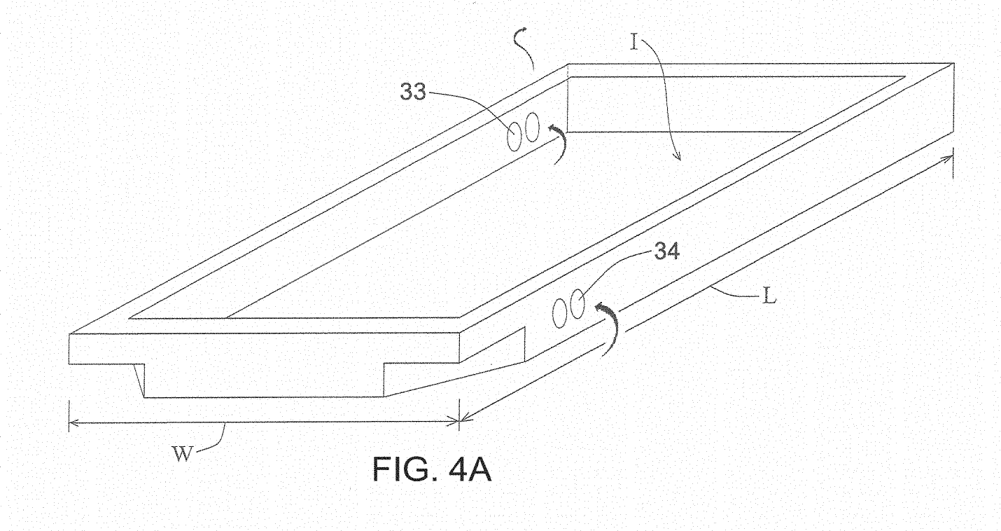

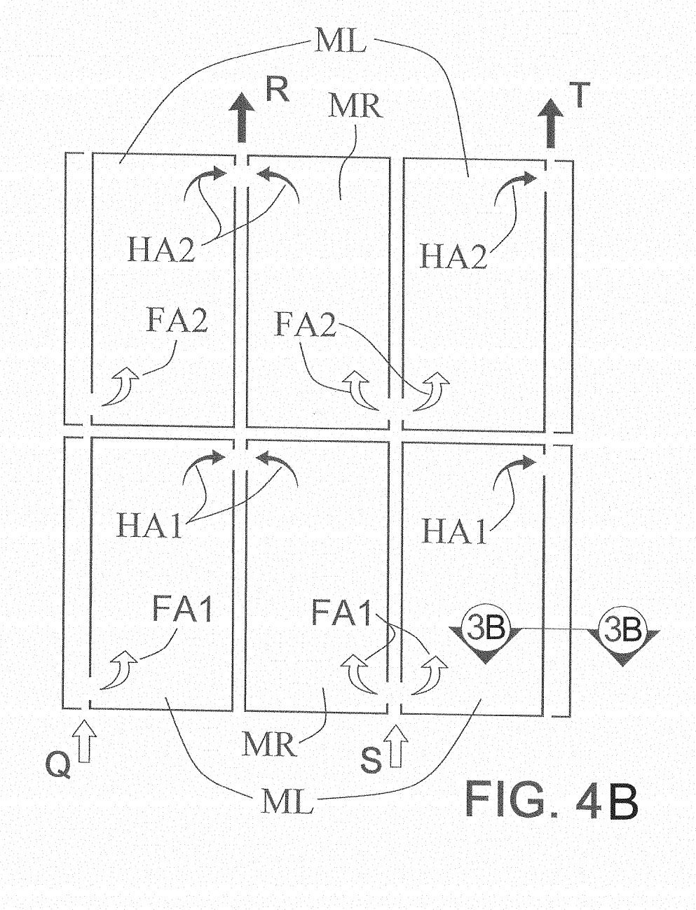

It may be noted that the term “modular” means that a system is expandable in order to increase the total system power by adding modules, for example, meaning that each module is compatible with the other modules in the system and can be connected (both electrically and mechanically) together. Modules are interchangeable and compatible with each other without any modification, except that, preferably, there are “right” and “left” modules, however, to connect in a manner as shown and described for FIG. 4B and its air flow channels.

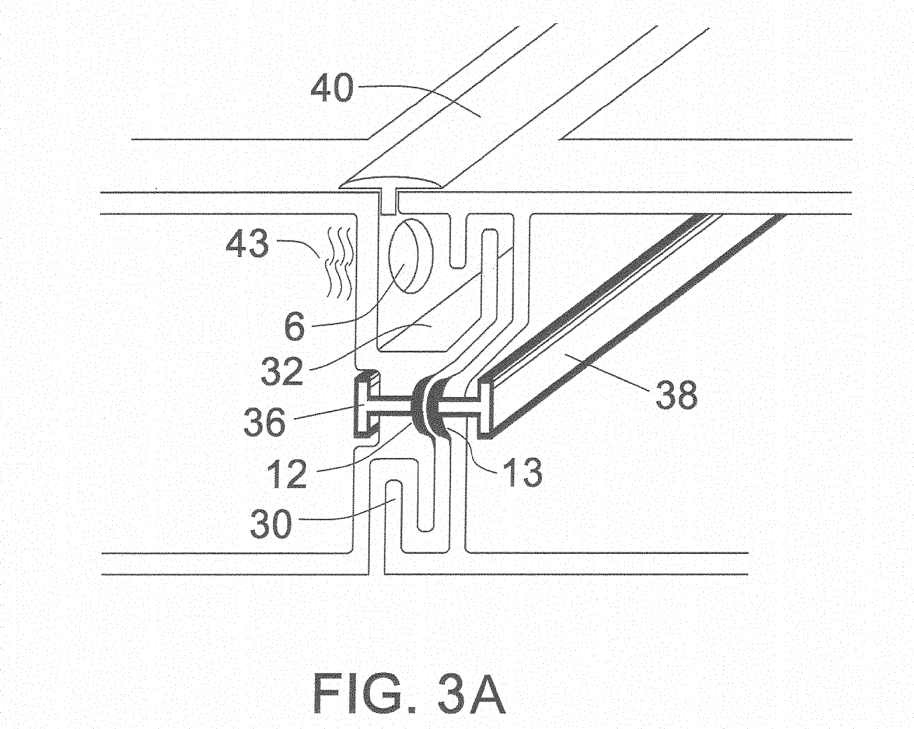

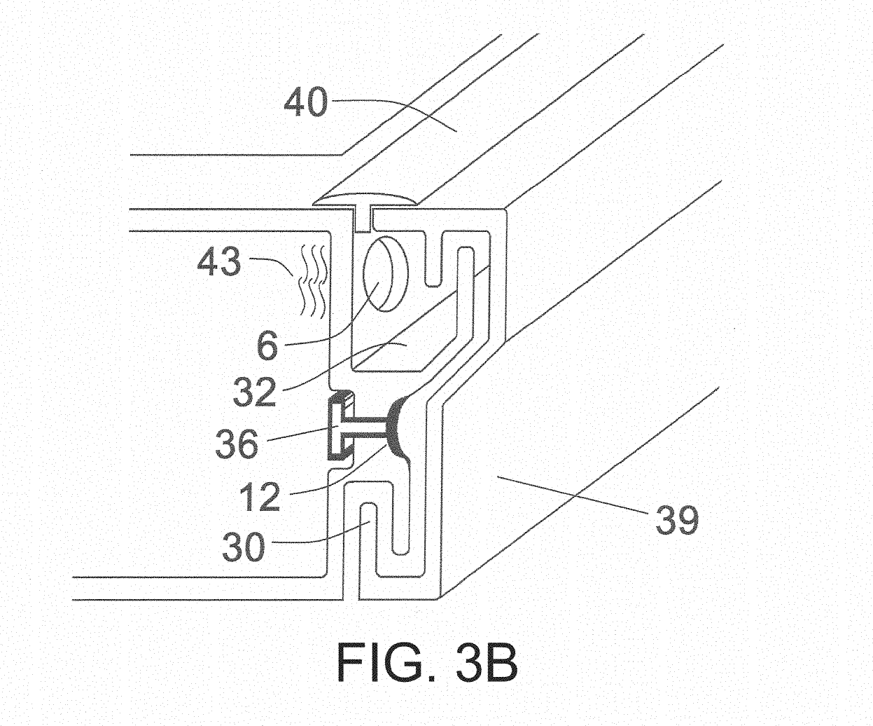

FIG. 1 shows a single module 100, which is fully functional without any other modules connected to it, thus, it is self-contained. The top surface of the module is a solar collector 1 that covers the entire, or substantially the entire, top surface. The enclosure 3 or “housing” is weatherproof and houses all of the electronics and wiring. In order to allow for the expansion of the system by interconnection of multiple modules, the module 100 has a mechanical track 5 that allows a second module to be slid into the track and connected to the first module 100. Openings for air flow 6 on the side (preferably a side edge) of module 100 are described in more detail below, regarding FIG. 3 and FIG. 4. There are two electrical connector sections in the track 5 (or “track assembly”) providing connection points for each of the electrical systems. The first track section is for DC power 7, and the other is for data/control 9. Each of these track sections have a conductive section/electrical fitting 12 that physically mates to the adjacent module connecting the circuiting between the two modules. See FIG. 3A. The external power receptacle 14 is on the bottom face of the corner wing, as shown in FIG. 1. This allows the outlet and plug to be protected from the weather. The extension cable 15 consisting of power and data wiring is plugged in to the receptacle and extended to the electrical loads to be served by the system. Plug strip 16 with receptacle 17 and indicator light 18 identifies which priority each receptacle is for load shedding. While one receptacle 17 and one indicator light 18 are called-out in FIG. 1, one may see three pairs of receptacle 17 and light 18 along the length of the strip 16. User interface device 19 in this instance is shown on a power strip, however it could be attached directly to the module or located remotely in the form of a phone or computer. The user interface device 19 displays system information and can receive user input to control the system. USB outlet and RJ45 port 20 are for connection of a data control cable. The warning indicator 2 is shown as a light connected directly to the module. The warning indicator 2 could be any audible or visual alarm and will indicate whether or not an electrical connection has been made with another module.

FIG. 2 illustrates an example of a system 200 with four modules, including one primary module 21 connected to three other subordinate modules 22. Each module has conductive bussing running the length of each interior side of the module 24, and along the interior top and bottom walls 26. View line 3A-3A shown in FIG. 2 is detailed in FIGS. 3A and 3B.

The cross-section of the interface (here, “interconnection” including mechanical and electrical connection) between two adjacent modules is shown in FIG. 3A. The mechanical track 30 of FIG. 3A is configured to provide a mating channel to slide the two modules together. As the modules are slid together along the channel track, and as the connection points 12 for the primary module, and connection 13 for the secondary module come into alignment, they will contact each other and make the electrical connection once the track travel has fully seated and come to a stop. The bus bar 36 in the primary module is connected to the bus bar 38 in the subordinate module via this connection. The top section of the channel has an airway trough 32 to provide an airway for venting of the interior of the modules. Each module has a hole or opening 6 on the sidewall of the enclosure to allow hot air to exit the enclosure and ventilate the air thru the channel and out the top of the channel. Passive heat transfer from the interior of the module to the outside air will occur as the heated air is drawn upward to the top of the channel and vented out. The bus bar 36 in the primary module is connected to the bus bar 38 in the subordinate module via this connection. Weather-strip 40 protects the channel from water entry. Whatever little water or moisture that may enter the channel will flow down the bottom of the airway trough 32, and drain out the bottom. Screen 43, against/over opening(s) 6, protects the entrance of the module from insects and debris, and only allows air to flow thru the opening.

As shown in FIG. 3B, a channel cover 39 is slid onto module sides (“side edges”) that are not adjacent to another module, for example, for an “outer” module such as shown at view line 3B-3B in FIG. 4B. This provides a channel for the air flow, and protects the channel, including its electrical elements, from the weather. The channel cover runs the length of the channel along the side of the module.

FIG. 4A is a schematic view of a module, with its top solar panel removed, and illustrating the interior space I of the module enclosure. Openings 33 and opening 34 (see also openings 6 in FIGS. 1, 3A and 3B) are at opposite ends of the module. In many embodiments, the orientation of the module on a slanted roof/surface will place the openings 33 (and the respective “top end” of the module) higher in elevation relative to openings 34 (and the respective “bottom end” of the module). Given such an orientation, FIG. 4A demonstrates an example of how the airflow travels thru a single module to ventilate heat from the interior I of the enclosure to the outside. Hot air inside the module rises to the top of the enclosure and is drawn to the outside thru the upper opening(s) 33 at the top end of the module. Cooler air from the outside is drawn in from the bottom of the enclosure thru the lower opening(s) 34 at the bottom end of the module. Heat from the solar panel at the top side of the enclosure, along with additional heat from other electronic components (not shown in FIG. 4A) will contribute to this process.

FIG. 4B illustrates how the airflow channels/passages may be established for air travel in a network/assembly of modules. Some of the modules (ML) have their fresh air openings on lower, left side edges, and other of the modules (MR) have their fresh air openings on lower, right side edges, with the hot air openings at the opposite side edges of each module. Therefore, a column of ML modules will be connected to an adjacent column of MR modules, next to another column of adjacent ML modules; this forms, from left to right in FIG. 4B, a fresh air channel Q at the far left, a hot air channel R, another fresh air channel S, and another hot air channel T. In other words, fresh air channels (Q and S) alternate with hot air channels (R and T). Thus, fresh air enters into the lower ends/corners of the modules at channels “Q” and “S” (at the side edges of the modules are located the fresh-air openings). See fresh air arrows FA1 to the lower three modules, and also fresh air arrows FA2 to the upper three modules. Thus, the hot air tends to leave the modules (see arrows HA1 for the lower modules, and arrows HA2 for the upper modules) from the upper openings, flowing into channels “R” and “T” and then out of those channels on the upper end of the module assembly. The hot air is drawn generally from the lower/bottom end of the assembly, to the upper/top end of the assembly, and, hence, to the top outside air. Specifically, the hot air exiting from each module flows into the channel along the end-to-end length of each of the modules, and flows through the channel toward the top end of the assembly of modules, to exit to the ambient air. This way, each channel maximizes the efficiency of the heat transfer, since hot air from one module will not enter another module on its way to the outside. The air entry point 34 of each module is at/near one end and one side edge of the module, and the air exit point 33 is at/near the opposite end and opposite side edge of the module, allowing the airflow to go across the entire surface area and volume that needs to be ventilated (along the entire or substantially the entire length L between said opposite ends, and across the entire or substantially the entire width W between the opposite side edges). Refer to FIG. 4A. In certain embodiments, this air does not flow through the battery chamber, but instead bypasses or is otherwise blocked from doing so. Channel cover 39 provides such a passage for the air flow on channel side edges not adjacent to another module; refer to FIG. 3B. It may be noted that the left and right side edges of the modules in a given row of the assembly in FIG. 4B are connected mechanically and electrically by the channels/tracks, as described herein, while the rows of modules may be connected together mechanically, by various fasteners for example, at their top and bottom side edges, if desired.

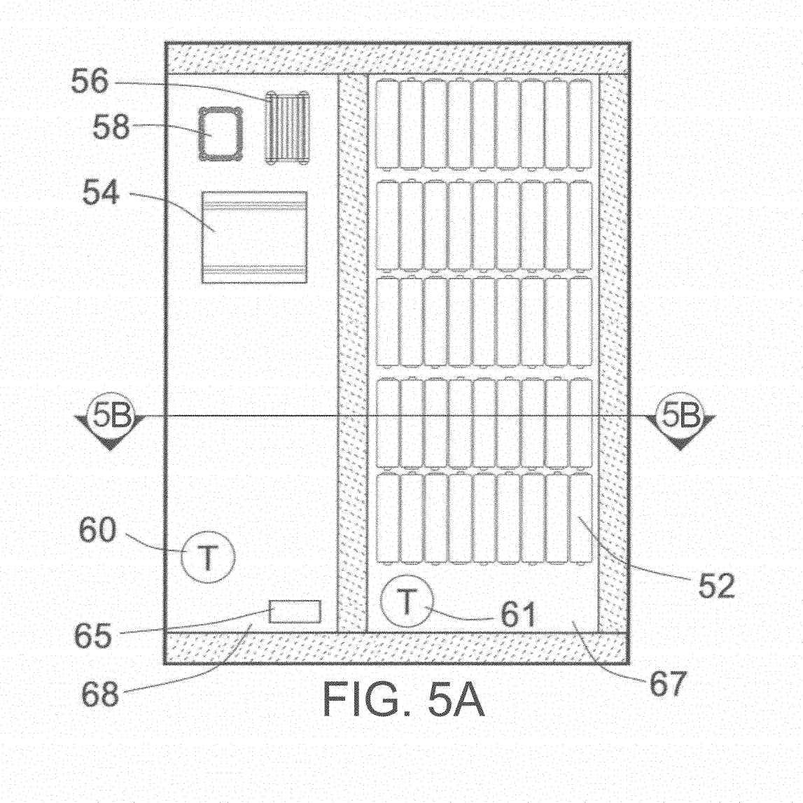

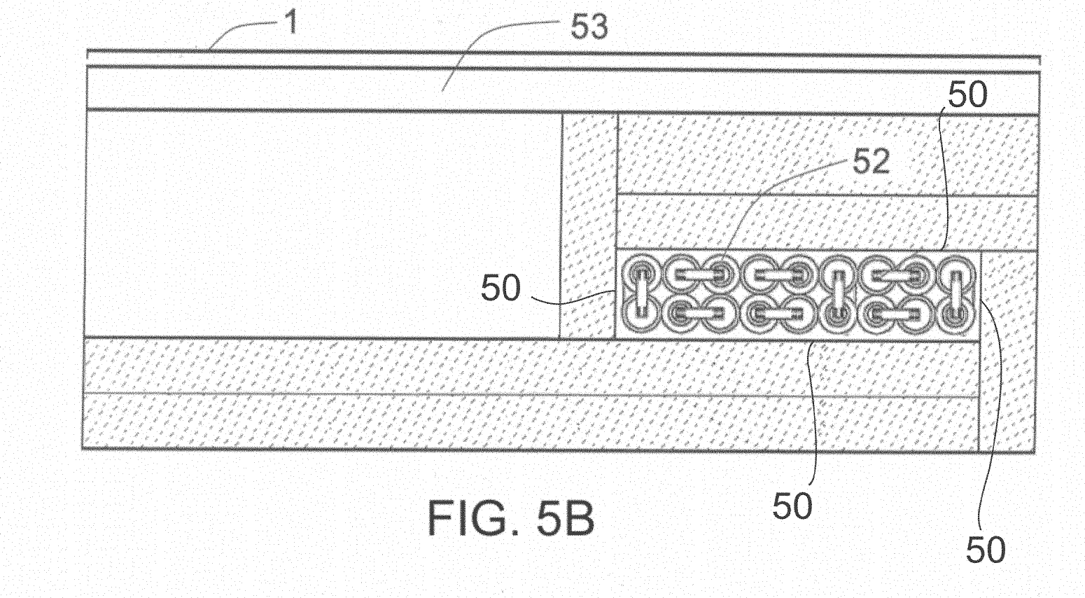

FIG. 5A shows the interior of the module, with all of the preferred components contained therein. All of the electrical components are in a separate compartment from the energy-storage device 52. This provides a thermal barrier to protect the energy-storage device 52 from the heat of the electronic components and the solar panel. Examples of the preferred Maximum Power Point Tracker (MPPT) 54, Charge Controller (CC) 56, Control System (CS) 58, Electronics compartment temperature sensor (T) 60, energy-storage device compartment temperature sensor 61, DC circuit protection and control 65, energy-storage device compartment 67, and Electronics Compartment 68, are illustrated, and it will be understood from this document and the drawings, combined with the average skill in the art, how these elements will be connected and operated.

FIG. 5B is a cross section of the enclosure illustrating the heat transfer and insulating features of the system. The energy-storage device 52 is insulated on all sides 50. There is a dead air space 53 beneath the entire solar panel 1 that provides a passageway for the airflow from the intake and exit holes in the sidewalls of the enclosure. This airspace keeps the back side of the solar panel 1 cool, and prevents excess heat from entering the enclosure.

FIGS. 6A, 6B and 6C illustrate the various types of modules and some, but not all, examples of how multiple modules may be connected together. FIGS. 6A, 6B and 6C give examples of various ratings which are not meant to be limiting in scope, but are only used as examples to illustrate how interconnected modules would work together. The simplest system consists of just one module; said just one module must be a P module so that it can communicate to the CS and provide all of the required functions. More complicated systems may comprise, consist essentially of, or consist of multiple modules connected mechanically and electrically into module assemblies. The additional modules, over and above said just one module, can be connected to the P module as subordinate modules. The S modules rely on the P module for control and interface to the CS. For the case where a system is larger (more power) than that which a P plus S system can handle, then an additional main module can be added to connect multiple P modules. In this case, the entire system control is thru the M module, with all of the P modules being secondary to the M module. By adding modules that can handle larger load sizes, even larger than the M module given in the example, the solar modular system is expandable according to power production needs of differing situations.

The row of modules in FIG. 6A shows possible system load ratings and possible local load ratings of each of the preferred module types. The load ratings are not to be confused with power production and power storage which have their own ratings. The S module 70 has a local load rating (for the individual module) of 500W, and a system load rating of 2.5 kW. The system load rating indicates that S can be placed within a network of modules of up to 2.5 kW, while the local load rating indicates how much power can be plugged directly into the module. The P module 72 has a local load rating of 2.5 kW (for the local network with its subordinate S type modules), and a system rating of 5 kW. The M module 74 has a local load rating of 10 kW and a system load rating of 20 kW.

The row of modules in FIG. 6B illustrates an example of a P module connected to four S modules on each side of the P module. A first set 76 of modules, therefore, may be said to be the four S modules on the left, plus the primary module P. A second set 78 of modules may be said to be the four S modules on the right that connect to P, parallel to the S modules of the first set 76. Since each module (P, S, M) may have a local production rating of 500W, the combined total power of all five modules (the P module plus four modules on one side of the P module) is 2500 watts, consistent with the local rating of 2.5 kW of P. Note that there are four additional S modules, each with a local production rating of 500 watts (0.5 kW), on the other side of the P module, for a total of eight S modules, which is 4 kW total. The P module only adds 500 additional watts to the total, for a total 4.5 kW. This is consistent with the 5 kW system load rating (see the 5 kW system rating for P).

In FIG. 6B, it may be noted that the 2.5 kW is the local load rating of P (only for the individual module itself), so if there were a P module with no other connected panels it could handle up to 2.5 kW in local loads (loads that are plugged directly in to the P module). The S modules can handle up to 500 watts in local loads, and up to 2.5 kW shared loads (if in a system as shown). Therefore, S modules are shown in FIG. 6B on either side of the P module, with 4 on each side and with each side of S modules being connected in parallel to the P module. If 8 S modules were on one side of the P module, the total connected load would exceed the 2.5 kW local load rating of P, and the CS would not allow the electrical connections of the excess modules to occur. Since there are only 4 S modules (four on each side of the P), any one of the individual S modules will never experience more than its system load rating of 2.5 kW and the P module will never experience more than its local load rating of 2.5 kW.

The rows of modules in FIG. 6C indicate how each of the P modules serve four S modules, and in turn feed into the M module. Each M module serves 3 P modules at 2.5 kW each for a total of 7.5 kW. Since the M module has a local load rating of 10 kW (greater than 2.5 kW) and a system load rating of 20 kW (greater than 7.5 kW), this configuration is well within the ratings of this example.

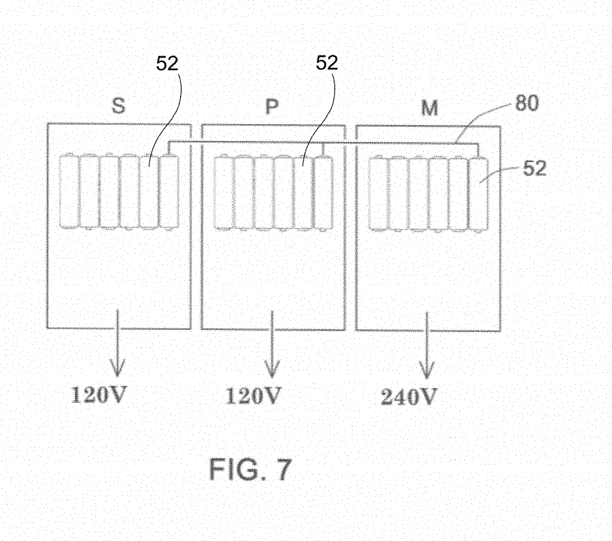

FIG. 7 illustrates the connection of modules via DC power 80, sharing the power by connecting all of the energy-storage devices 52 of the 3 modules (S, P, and M modules) in parallel. Note the 120V from modules S and P, and the 240V from module M. The modules can be configured to allow for high DC voltage where the high DC voltage is above 100V or above 50V.

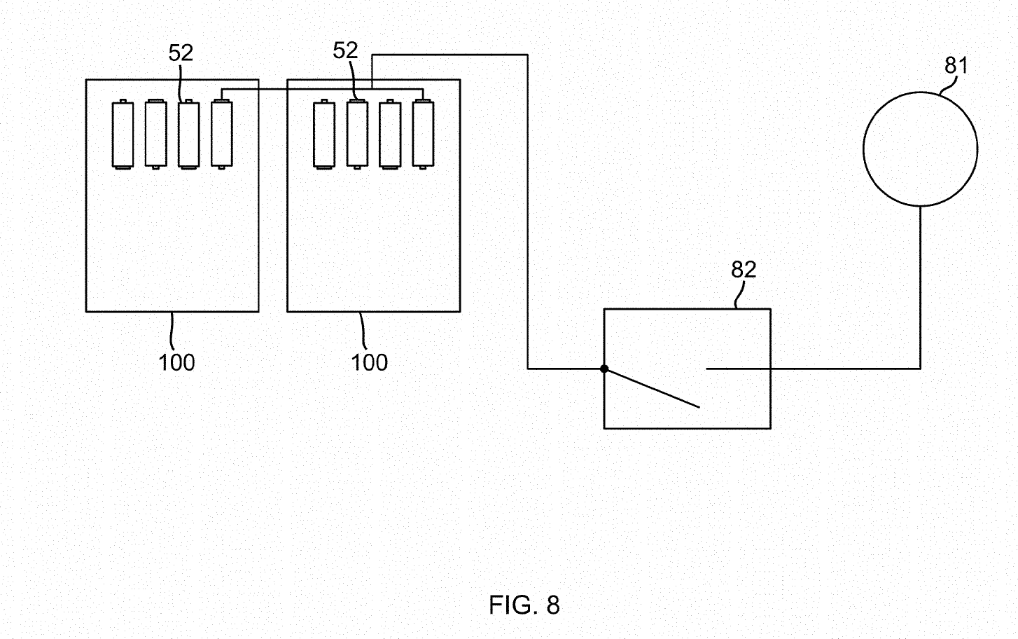

FIG. 8 shows modules 100 connected to an alternate power supply 81 by means of a switch 82. When the energy-storage device 52 of the modules 100 drop below a predetermined threshold level, the modules 100 will draw power from the alternate power supply 81 to charge the energy-storage devices 52.

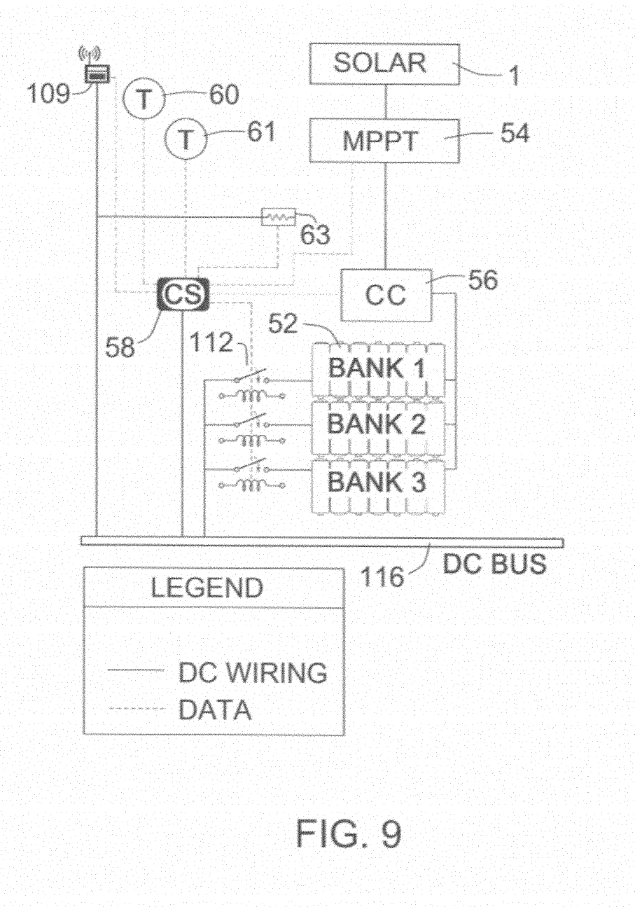

FIG. 9 is a wiring diagram of an individual module. The solar panel 1 is connected to the maximum power point tracking (MPPT) device 54 which is connected to the charge controller 56 when charging the energy-storage device 52. The charge controller 56 charges the energy-storage device 52, and each of the energy-storage devices can be isolated from the DC power bus by relays 112. The control system 58 controls all of the system devices as shown including the MPPT 54, charge controller 56, electronics temperature sensor 60, battery temperature sensor 61, and heater 63. The energy-storage device delivers power to the DC power bus 116 that provides power to all local devices, and is also connected to adjacent modules as described in FIG. 1 and FIG. 2. Wireless device 109 connects to the control system to allow remote wireless monitoring and control of the system. Relays 108 and 110 allow the inverter to be isolated from the system.

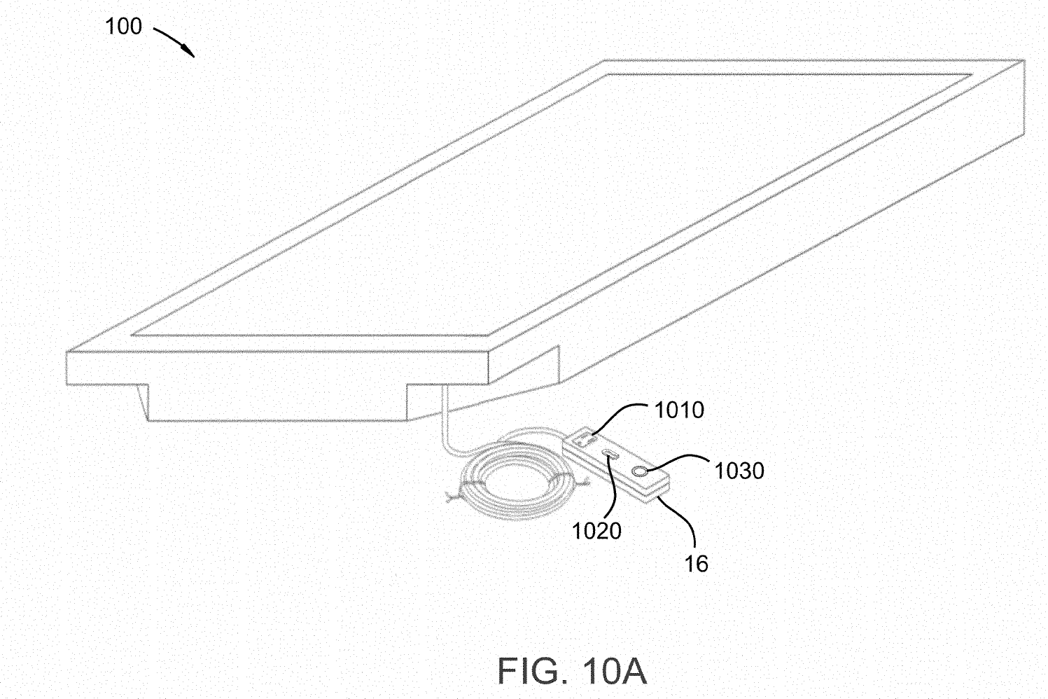

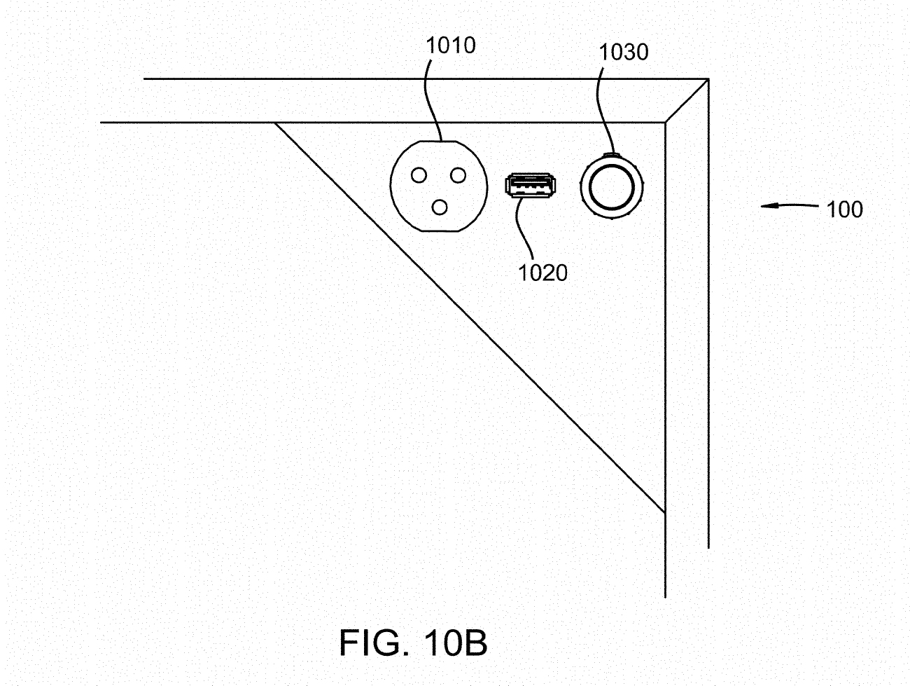

FIG. 10A is an isometric view of a single module 100 depicting one embodiment of the outlets (1010, 1020, 1030) serving the loads. In the depicted embodiment, the outlets (1010, 1020, 1030) are housed on a power strip 16 that is attached to the module 100 via an electrical cord. According to the example embodiment, the outlets (1010, 1020, 1030) are various types including a cigarette lighter receptacle 1030, a USB receptacle 1020, or an XLR receptacle connector 1010 all serving various voltages.

FIG. 10B is an isometric view of an example embodiment wherein the outlets (1010, 1020, 1030) are attached directly to the module 100. According to the example embodiment, the outlets (1010, 1020, 1030) are various types including a cigarette lighter receptacle 1030, a USB receptacle 1020, or an XLR receptacle connector 1010 all serving various voltages.

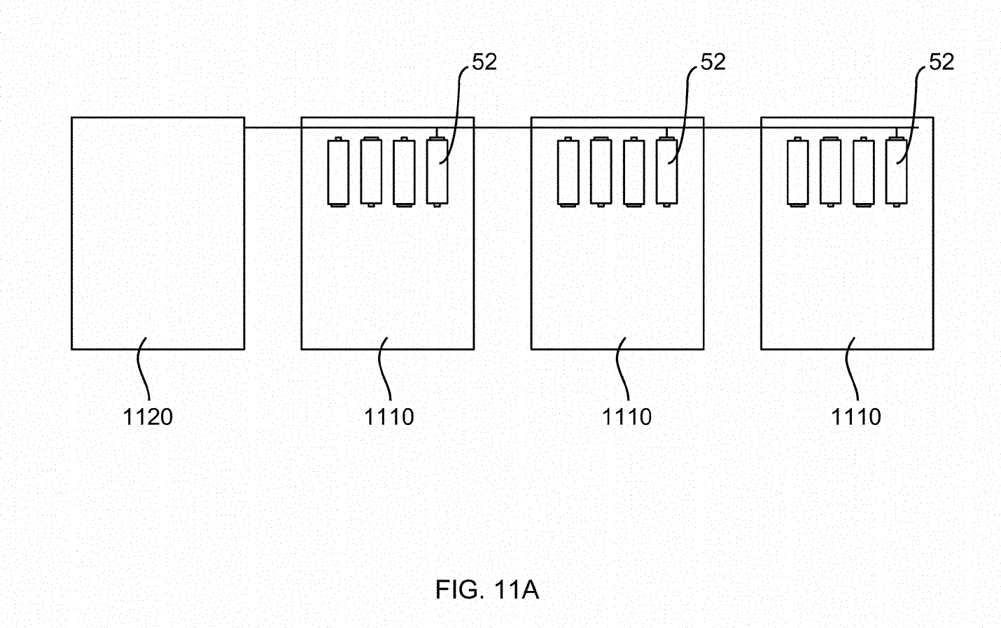

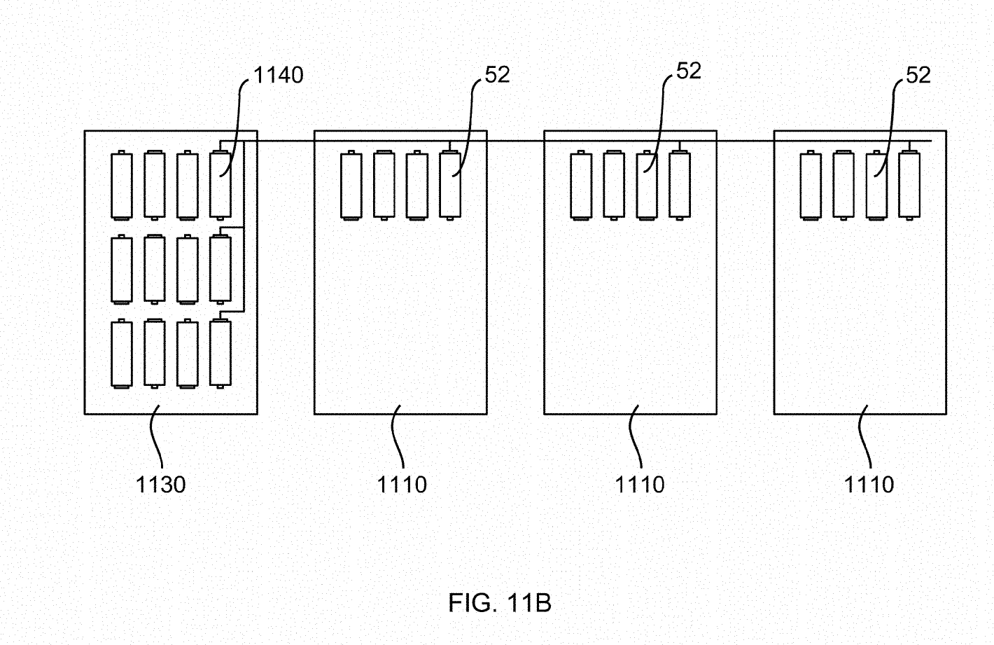

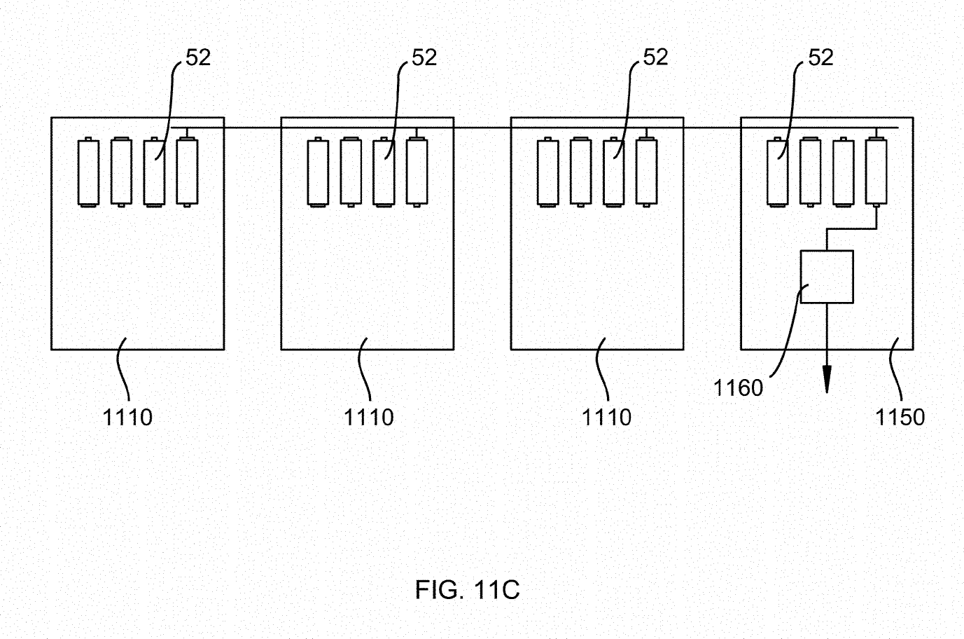

FIGS. 11A, 11B and 11C show that modules of the solar-powered system may be identified according to their function. According to these functional identifications there are four different types of modules: normal modules, production modules, storage modules and inverter modules. These four different types of modules may be included or omitted from the solar-powered modular system according to the needs of the user based on varying conditions.

FIG. 11A shows the connection of a production module 1120 into a system of normal modules 1110, the normal modules 1110 being S modules, P modules or M modules. The normal modules 1110 each contain an energy-storage device 52, but the production module 1120 does not. This is because the production module 1120 does not store energy, but only produces solar energy. As an example, if the normal modules 1110 of the system are not producing enough solar power to fully charge their energy-storage devices 52, then a production module 1120 may be included in the system to help charge the energy storage devices 52 of the normal modules 1110 to full capacity. The production module 1120 would comply with all system load rating requirements as determined by the CS. The production module 1120 may have ratings equal to S modules, P modules or M modules, in other words the production module 1120 may be an S module, P module or M module.

FIG. 11B shows the connection of a storage module 1130 into a system of normal modules 1110, the normal modules 1110 being S modules, P modules or M modules. The normal modules 1110 each contain an energy-storage device 52, and the storage module 1130 contains an energy-storage device 1140 that has a greater energy storing capacity than the other energy-storage devices 52. As an example, if the normal modules 1110 are producing solar power in excess of what their energy-storage devices 52 are capable of storing, a storage module 1130 may be connected into the system in order to increase energy storage capacity of the system. The storage module 1130 complies with all system load rating requirements as determined by the CS and may have ratings equal to S modules, P modules, or M modules. Another example of the necessity of additional energy storage capacity is when the night-time electrical load exceeds the demand served by existing minimal storage capacity. There may be enough solar charging capacity during the day, but not enough stored energy to serve the night-time loads. The data that informs this decision about whether or not to add additional production module or storage module is indicated by the control system. The CS monitors energy production and storage capacity. Based on the specific use, electrical loads and when these loads occur (daytime use or night-time), solar energy production during the day, the CS may determine what type of modules should be added. The use of the system, and therefore the system requirements may change over time, so that the CS may determine 1) if additional modules are needed, and 2) which types are required. The additional modules may be added potentially more than once over a period of time as needed.

FIG. 11C shows an inverter module 1150 connected into a system of normal modules 1110. Both the inverter module 1150 and the normal modules 1110 contain energy-storage devices 52. The inverter module 1150 contains an inverter 1160. As an example, if it is desired to connect the system of modules to a load requiring AC power, an inverter module 1150 may be included in the system. The inverter module 1150 has a system load rating greater than or equal to all other connected modules of the system in order to handle all power feeding into it that it must invert to feed to the AC load. In other words, the inverter module 1150 has ratings equal to either the P module or M module.

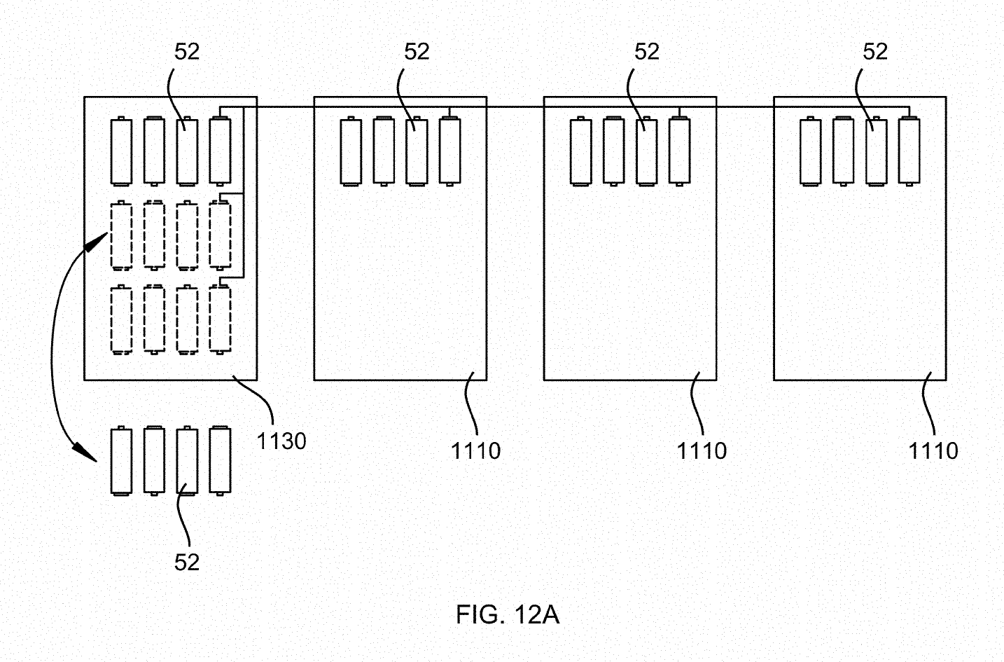

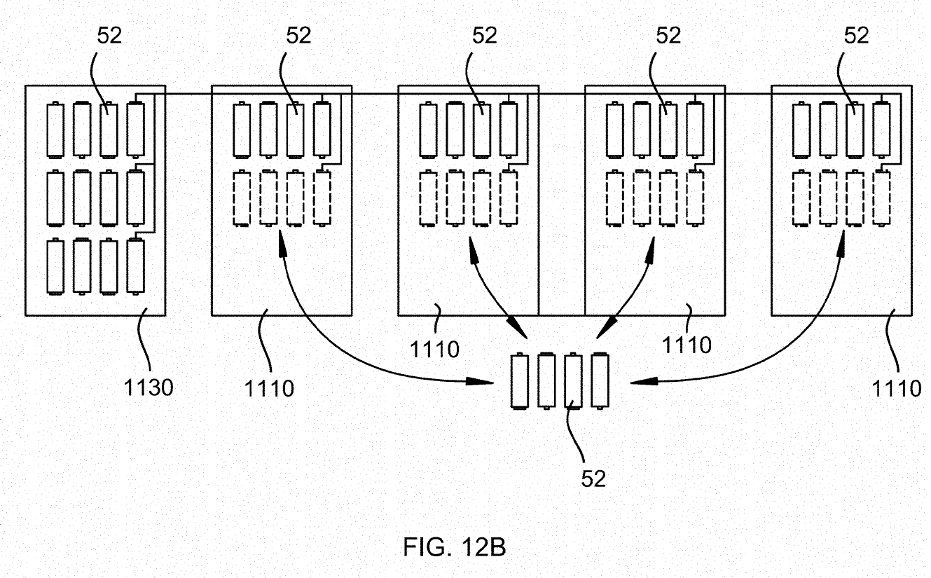

FIG. 12A shows the connection of a storage module 1130 into a system of normal modules 1110. The energy-storage devices 52 of the storage module 1130 can removed from the module or added to the module. This allows for the energy storing capacity of the system to be changed by the user due to varying system requirements.

FIG. 12B shows the connection of a storage module 1130 into a system of normal modules 1110. The storage module 1130 has more energy storing capacity than the normal modules 1110 because of more energy-storage devices 52. However, in this particular demonstration of the system, the normal modules 1110 may have energy-storage devices 52 added into the module or removed from the module. Thus, the normal modules may have their energy storing capacity changed by the user and based on the needs of the user. In order to increase energy storing capacity of the system, a storage module 1130 with a large energy-storing capacity may be connected into the system, or additional energy-storage devices 52 may be added to the normal modules 1110.

Certain embodiments of the invention may be described as a customizable modular solar power system, preferably for installation on a roof or other elevated location that receives solar insolation. The preferred system comprises multiple modules each having photovoltaic cells/panel(s), wherein a certain type of module (a primary module) is designed so that it can operate on its own, as a single, self-contained solar module providing DC power to one or more loads. The primary module, in addition to a solar panel(s) and elements to produce DC power, also comprises control and/or monitoring and/or communication/wireless apparatus for the entire assembly (the entire “system”). Additional, subordinate module(s) may also be provided for mechanical and electrical attachment to the primary module, to increase DC power production. Therefore, preferably each module (both primary and subordinate) is designed to connect to and work with other modules, for higher power output, by means of each module being adapted to work at the full system load rating of the entire system. Therefore, up to a predetermined number of subordinate modules may be connected electrically in parallel to the primary module, and preferably also mechanically connected, to be secured into a single structural unit. Further, in certain embodiments, multiple of the primary-module-plus-subordinate-module assemblies (P plus S assemblies) may be connected in parallel to a main module, that may comprise additional of said control and/or monitoring and/or communication/wireless apparatus for the entire assembly (entire system of two or more P plus S assemblies connected to M).

In the assemblies/systems of the above paragraph, each module preferably comprises a module housing that holds the solar panel(s) on one or more of its surfaces (preferably on a top, broad and flat surface), wherein the solar panel(s) may be of any type such as a flexible solar panel or rigid solar panels or cells, and of any composition currently known or developed in the future. The module housing contains in its interior space the other elements needed for the module operation, control, and protection, wherein the housing is further adapted to include ports for required operative connections (via the “outlets” or other electrical connection sites) to other modules and/or to loads. The modules, therefore, may be described in many embodiments as separate boxes, all of the same or approximately the same dimensions, that can be stacked in a courier-approved-size package, and shipped to a user. Then, the modules may easily be placed on a roof or other support and connected together and made operative without significant knowledge except to read instructions included with the package. Preferably, the connection is a convenient slide-together or snap-together connection that serves both mechanical and electrical connection, but, alternatively, the modules may be mechanically connected together by fasteners, clips, plates, racks, or other connectors, and plug-in wiring may be used to make the electrical connections.

The elements in and on each module for operation of each module of the above two paragraphs may comprise, consist essentially of, or consist of, elements to generate and store solar energy, and to provide DC power, to a load(s) that is/are outside the module but electrically connected (typically plugged into a receptacle) to a power outlet of the module or to a power outlet of the system/assembly of modules. Said elements in each module may include the solar cells/panel(s) (such as photovoltaic cells/panel(s)), one or more batteries or other energy storage devices, a Maximum Power Point Tracker (MPPT) such as one available commercially and understood in the art, a charge controller (CC), a control system (CS), relays to isolate the battery/storage-device from the DC power bus, an electronics compartment temperature sensor, a battery/energy-storage compartment temperature sensor, heater, DC circuit protection and control, and a wireless device connected to the control system to allow remote wireless monitoring and control of the system.

Certain embodiments may comprise, consist essentially of, or consist of, the elements schematically portrayed in FIG. 9. These elements will typically be separated to be contained within a battery compartment, and an electronics compartment, inside the housing of the module.

These elements, of the previous three paragraphs, are provided and operationally connected, when multiple of the modules are connected into the multiple-module system, so that each individual module is able to collect (via the solar panel), store (in batteries or other energy storage system), and deliver to external loads the energy collected by the solar panel, with the capacity to handle a total higher load than just one module. Said elements of the module and their particular operational connection are important because each module of the system must be: 1) compatible with the other modules (mechanically and electrically), and 2) have a system load rating high enough to handle all of the power over the entire system, and 3) have a control system to manage the power (since it is shared over the entire system). Regarding the item no. 1 compatible electrical operational connections, it is necessary to electrically connect the DC wiring of each module to the DC wiring of the other modules in a given group/assembly of modules. Regarding the item no. 2 system load rating for each module being high enough to handle all of the power over the entire system, this is important because: a) one cannot combine multiple systems or modules unless the total system is capable of supporting the combined loads, b) the combined loads vary depending on how many modules are connected together, and c) the modules and their operational connection must be designed to accommodate this variance. Regarding the item no. 3 control of operational connection, the system comprises a control system and (preferably wireless) communication to a control station/unit, to manage operations of each module (“in-box” or “within a given module”) and also of the system as a whole (that is, control of functions “out of the box”, that is, “between modules of the system” and “between the system and the loads”), for example, energy storage in the batteries/energy-storage and load shedding. Load shedding on the load side of the system allows energy management that conserves power when the energy storage system (batteries or the like) is low.

Certain embodiments, such as those described in the five paragraphs immediately above, may include one or more of the following features:
a) a mechanical channel or track to mechanically and electrically connect modules;
b) air flow to allow cooling of interior of module enclosure(s), which air flow may in certain embodiments be through said mechanical channel or track;
c) optional heating unit for heating batteries in extreme cold climates;
d) insulated batteries;
e) phase change material to even out the temperature swings;
f) light weight energy storage system like LiFE PO4 batteries or ultra-capacitors;
g) control system (CS) including energy management system;
h) MPPT shared by both inverter and charge controller (which saves manufacturing costs);
i) optional cooling fan controlled by the CS;
j) Storage Module(s) that have increased storage capacity;
k) Production Module(s) that increase solar power production; and/or
l) Inverter Module(s) that allow conversion to AC power.

Certain embodiments, such as those described in the six paragraphs immediately above, may include one or more of the following features:
a) the total system is preferably organized with a hierarchy of a “primary” module that serves multiple subordinate or “secondary” modules;
b) primary modules may be connected to one “main” module that serves multiple primary modules with their attached subordinate modules;
c) the control system controls not only the local module specific functions, but also controls and manages the power between modules and over the entire system, and, hence, also the power available from the entire system;
d) the CS isolates faults from the system, for example, disconnecting individual battery banks, disconnecting faulty solar panels, disconnecting and isolating faulty inverters; and/or
e) the CS interconnects all of the systems of the combined modules that allows the entire system to operate as a whole, for example, wherein the energy generation systems (solar) can charge any and all of the energy storage systems within the entire system, so that the combined energy storage can serve any and all connected loads.

Certain embodiments may be described as: A solar-powered modular system comprising: a plurality of modules, each comprising a housing, a solar panel on at least one outer surface of the housing that is adapted to produce power from solar insolation, a DC system comprising an energy-storage device, a charge controller that controls charging of the energy-storage device from energy produced by the solar panel, DC wiring and a DC outlet, each of the plurality of modules being electrically connected in parallel to form a module assembly for connection to power one or more electrical loads; wherein the DC systems of the modules are electrically connected in parallel; and wherein each of the modules has a system load rating equal to or greater than a sum of maximum power production of each of the electrically-connected modules, so that the module assembly is adapted to be connected to, and to power, said one or more electrical loads that total to be a higher total load than each of said modules is adapted to power individually. Therefore, in certain embodiments there may be subordinate modules operatively (electrically) connected in parallel to a primary module that comprises control capability, wherein all the modules of such an assembly are preferably in parallel; and, in certain embodiments, multiple of such primary modules (with the connected subordinate modules) may be connected in parallel to a main module that has further control capability, wherein all the modules of such an assembly are in parallel.

Certain embodiments may be described as: a solar-powered modular system comprising: a first set of modules, each comprising a housing, a solar panel on at least one outer surface of the housing that is adapted to produce power from solar insolation, a DC system comprising an energy-storage device, a charge controller that controls charging of the energy-storage device from energy produced by the solar panel, DC wiring and a DC outlet; each of the plurality of modules being electrically connected in parallel to form a module assembly for connection to power one or more electrical loads; wherein the DC systems of the modules are electrically connected in parallel; and wherein said first set of modules comprises one primary module and subordinate modules, wherein the primary module further comprises a control system adapted to monitor and control the energy-storage device of each of the subordinate modules; and the solar-powered modular system further comprising a second set of modules comprising subordinate modules that are connected in parallel to said primary module of said first set in parallel to the subordinate modules of said first set, wherein said control system of the primary module is adapted to monitor and control the energy-storage device of each of the subordinate modules of said second set; and wherein each of the subordinate modules of said first set has a system load rating equal to or greater than a sum of maximum power production of each of the first set subordinate modules and the primary module, wherein each of the subordinate modules of said second set has a system load rating equal to or greater than a sum of maximum power production of each of the second set subordinate modules and the primary module, and the primary module has a system load rating equal to or greater than a sum of all of the modules of said first set and said second set, so that the primary module is adapted to be connected to, and to power, said one or more electrical loads that total to be a higher total load than each of said modules of the first set and the second set is adapted to power individually.

Although this invention has been described above with reference to particular means, materials and embodiments, it is to be understood that the invention is not limited to these disclosed particulars, but extends instead to all equivalents within the scope of the following claims.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

1. A solar-powered modular system comprising:
one or more production modules comprising:
a first housing and a first solar panel that produces power on at least one outer surface of the first housing;
one or more storage modules comprising:
a second housing and a second solar panel that produces power on at least one outer surface of the second housing;
an energy-storage device; a control system; a processor; a memory; one or more electrical relays; electrical wiring and one or more outlets;
wherein the production modules and storage modules comprise a compatibility based on a predetermined number and type of modules and load capacity of the connected production and storage modules;
wherein each module in a group of production and storage modules has a system load capacity equal to or greater than a sum of the maximum power capacity of the group of modules;
wherein the plurality of storage and production modules are electrically connected in parallel to form a module assembly to power one or more electrical loads;
wherein logic stored in the memory allows only the compatible storage and production modules of the plurality of modules to be electrically connected to each other via the one or more relays; and
wherein the control system monitors the storage capacity, power production and power usage over a period of time to determine if additional production capacity or storage capacity is required; and
wherein the control system communicates to a user that the system requires addition of the compatible production or storage modules based on the power usage.

2. The solar-powered modular system of claim 1, the system further comprising one or more inverter modules, the inverter modules comprising:
a third housing and a third solar panel that produces power on at least one outer surface of the third housing; a DC to AC inverter; a control system; a processor; a memory; one or more electrical relays; electrical wiring; and one or more outlets.

3. The solar-powered modular system of claim 1, wherein the one or more storage modules further comprise one or more removable energy-storage devices allowing energy storage capacity to be increased by adding more of the one or more of the energy-storage devices as system energy storage requirements increase.

4. The solar-powered modular system of claim 1, further comprising a user interface device in communication with the processor and memory allowing monitoring and control of the system.

5. The solar-powered modular system of claim 1, wherein the modules are connected by electrical connectors comprising wiring, plugs and receptacles specific to the compatible modules.

6. The solar-powered modular system of claim 1, wherein the control system is in communication with the processor, the memory, and the user interface.

7. The solar-powered modular system of claim 4, wherein all modules in the solar-powered modular system are connected to and controlled by the control system.

8. The solar-powered modular system of claim 4, further comprising multiple power outlets to power multiple of said electrical loads, wherein the power outlets are each assigned a level of importance from low importance to high importance, and wherein the control system turns on or off one or more of the multiple power outlets based on user defined importance.

9. The solar-powered modular system of claim 8, wherein the multiple of said electrical loads are detachably plugged-in to the multiple power outlets so a user selects what load is plugged-in to each power outlet according to a determination by the user of the importance of each load.

10. The solar-powered modular system of claim 4, comprising a connection to an alternate power supply, wherein the control system causes power to be drawn from the alternate power supply to charge the energy-storage devices of the multiple modules when stored energy in the energy-storage devices drop below a predetermined threshold level.

11. The solar-powered modular system of claim 1, wherein the plurality of modules are mechanically connected by each of the modules comprising a channel/track, wherein the channel/track of each module slidably mates with the cooperating channel/track of an adjacent module to mechanically secure and electrically connect the modules together.

12. The solar-powered modular system of claim 1, wherein the housing comprises apertures for air flow for cooling of an interior space inside each of the modules of the plurality modules.

13. The solar-powered modular system of claim 1, comprising a heating unit inside the housing for heating the energy-storage devices in extreme-cold climates.

14. The solar-powered modular system of claim 1, comprising insulation inside the housing and surrounding the energy-storage devices.

15. The solar-powered modular system of claim 1, comprising phase change material inside the housing to even out the temperature swings inside the housing.

16. The solar-powered modular system of claim 1, wherein said solar panel of each module charges the energy-storage devices of all of the modules.

17. The solar-powered modular system of claim 1, wherein the one or more outlets are attached directly to the housing or via an electrical cord and wherein the one or more outlets are different types serving different voltages.

18. The solar-powered modular system of claim 4, wherein the user interface device is a device comprising one or more of a processor, cell phone, mobile device, computer, computer network, cloud network.

19. The solar-powered modular system of claim 4, wherein the user interface device is wirelessly connected to the control system, the user interface device comprising one or more of:
display screen;
control buttons;
touch screen display;
LED indicator lights; and
audible alerts.

20. The solar-powered modular system of claim 1, wherein the plurality of storage and production modules are electrically connected in parallel by one or more bus bars comprising a solid or tubular cross-sectional shape selected from the group consisting of circles, conic sections, and polygons, such as circles, cones, ellipse, ovals, squares, rectangles, triangles, hexagons, octagons, and pentagons, or combinations thereof.
